(19) United States
(12) Patent Application Publication
(10) Pub. No.: US 2003/0161427 A1
(43) Pub. Date: Aug. 28, 2003

(54) Clock-signal generating circuit and data-extracting circuit incorporating the same

(76) Inventor: Tadashi Nonaka, Fujisawa-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/373,718

(22) Filed: Feb. 27, 2003

(30) Foreign Application Priority Data
Feb. 27, 2002 (JP) 2002-051877

(51) Int. Cl. H03K 19/00; H04L 7/00

(52) U.S. Cl. 375/355

(57) ABSTRACT

A clock-signal generating circuit is disclosed, which comprises a plurality of data-rate delay circuits which are connected in cascade, the data-rate delay circuit at a first stage being connected to receive serial data, and each of the data-rate delay circuits being configured to delay input data by the rate of the serial data and output, for each bit of the serial data, one pulse signal shifted in phase from the input data by 1/n of the data-rate of the input serial data (n is an integer), and a logic circuit which synthesizes the pulse signals output from the data-rate delay circuits to output a sampling clock signal for extracting data from the serial data.

### CROSS-REFERENCE TO RELATED APPLICATIONS

This application is based upon and claims the benefit of priority from the prior Japanese Patent Application No. 2002-51877, filed Feb. 27, 2002, the entire contents of which are incorporated herein by reference.

### BACKGROUND OF THE INVENTION

1. Field of the Invention

The present invention relates to a clock-signal generating circuit. It also relates to a data-extracting circuit which incorporates the clock-signal generating circuit and which is desired for use in, for example, high-speed data communication.

2. Description of the Related Art

FIG. 4 illustrates a data communications system. As FIG. 4 shows, the system comprises communication apparatuses T and R. The apparatus T has a clock signal source. To receive serial data from the data-transmitting apparatus T, the data-receiving apparatus R must use a clock signal of the same frequency as the clock signal used in the apparatus T. In other words, the clock signal in the receiving apparatus R must have the same frequency fr as the clock signal used in the transmitting apparatus T.

In the data-receiving apparatus R, however, if the clock signal used to sample the data shifts in phase as seen from FIG. 5, then a frequency offset occurs between the clock signal used in the data-receiving apparatus R and the clock signal used in the data-transmitting apparatus T. The frequency offset results in timing difference between the data received at the apparatus R and the clock signal used in the apparatus R. (The data is, for example, differential signal type data.) The timing difference may make it impossible to reproduce the data the apparatus R has received. To avoid this, the data-receiving apparatus R uses a sampling clock signal synchronous with the serial data received, thereby sampling the serial data, or reproducing the serial data.

Various types of circuits for generating sampling clock signals are known. Among them is a circuit that generates a plurality of clock signals of different phases.

FIG. 6 depicts a conventional data-extracting circuit for use in the data-receiving apparatus R shown in FIG. 4. This circuit uses a multi-clock signal generating circuit in which clock signals of different phases are generated. FIG. 7 illustrates a timing signal used in the data-extracting circuit of FIG. 6.

The data-extracting circuit shown in FIG. 6 comprises a multi-clock-signal generating circuit 51, a signal-selecting circuit 52, a phase-comparing circuit 53, a clock-signal control circuit 54, and a flip-flop circuit 55. The multi-clock-signal generating circuit 51 generates n clock signals of different phases, CK1, CK2, . . . CKn, which are supplied to the clock-selecting circuit 52. The circuit 52 selects one of the clock signals CK1, CK2, CKn. The phase-comparing circuit 53 compares the input data with the clock signal selected by the circuit 52, in terms of leading edge (or trailing edge). The outputs UP and DN of the phase-comparing circuit 53 are supplied to the clock-signal control circuit 54. The circuit 54 generates a control signal from the outputs UP and DN. The control signal is supplied to the signal-selecting circuit 52. In accordance with the control signal the circuit 52 selects a clock signal of the most appropriate phase from the signals CK1, CK2, . . . CKn. The clock signal thus selected is supplied to the flip-flop circuit 55. Using the clock signal selected the flip-flop circuit 55 samples the data receives, thus reproducing the data.

In the conventional data-extracting circuit of FIG. 6, the circuit 51 needs to generate many clock signal of different phases so that the signal selected by the circuit may be very similar in phase to the data received. The greater the number of clock signals generated the smaller the phase difference between them. The smaller the phase difference, the more complicated the wiring pattern.

To enable the signal-selecting circuit 52 to select such an optimal clock signal having such a phase that the logic level changes at the midpoint in the bit period of the data the data-extracting circuit has received, phase comparison at least n/2 times needs to be performed.

The data received may change in value after a long time as is illustrated in FIG. 7. In this case, the data-extracting circuit may fail to reproduce the data until the clock signal of the most desirable phase is selected.

In the Hi-speed mode of the USB (Universal Serial Bus) 2.0 standard, the longest period (longest bit-length), in which the data received remains unchanged, is 7-bit period. In the 8B10B data-transmission system, the longest period is 9-bit period.

As specified above, in the conventional data-extracting circuit, the circuit 51 needs to generate many clock signal of different phases so that the signal selected by the circuit may be very similar in phase to the data received. The greater the number of clock signals generated the smaller the phase difference between them. The smaller the phase difference, the more complicated the wiring pattern. To make the matter worse, the data-extracting circuit may fail to reproduce data until the clock signal of the most desirable phase is selected.

### BRIEF SUMMARY OF THE INVENTION

According to an aspect of the present invention, there is provided a clock-signal generating circuit comprising a plurality of data-rate delay circuits which are connected in cascade, the data-rate delay circuit at a first stage being connected to receive serial data, and each of the data-rate delay circuits being configured to delay input data by the rate of the serial data and output, for each bit of the serial data, one pulse signal shifted in phase from the input data by 1/n of the data-rate of the input serial data (n is an integer); and a logic circuit which synthesizes the pulse signals output from the data-rate delay circuits to output a sampling clock signal for extracting data from the serial data.

According to another aspect of the present invention, there is provided a clock-signal generating circuit comprising a plurality of data-rate delay circuits which are connected in cascade, the data-rate delay circuit at a first stage being connected to receive serial data, and each of the data-rate delay circuits being configured to delay input data by the rate of the serial data and output, for each bit of the serial data, one pulse signal shifted in phase from the input data by 1/n of the data-rate of the input serial data (n is an integer); a logic circuit which performs a logic operation OR on the pulse signals output from the data-rate delay circuits to output a sampling clock signal; and a data-reproducing circuit which receives the serial data and samples the serial data by using the sampling clock signal output from the logic circuit to reproduce data.

### BRIEF DESCRIPTION OF THE SEVERAL VIEWS OF THE DRAWING

FIG. 1 is a circuit diagram showing a data-extracting circuit that incorporates a clock-signal generating circuit according to a first embodiment of this invention;

FIG. 2 is a timing chart illustrating various signals and explaining the operation of the data-extracting circuit shown in FIG. 1;

FIG. 3 is a circuit diagram depicting a data-extracting circuit that incorporates a clock-signal generating circuit according to a second embodiment of the invention;

FIG. 4 is a block diagram of a data communications system;

FIG. 5 is a timing chart, showing how a frequency offset occurs in the data-receiving apparatus R provided in the system of FIG. 4 and how the sampling clock signal becomes asynchronous with the input serial data, making it impossible to reproduce the data in the data-receiving apparatus;

FIG. 6 is a circuit diagram of the data-extracting circuit incorporated in the data-receiving apparatus R, which incorporates a conventional multi-clock signal generating circuit; and

FIG. 7 is a timing chart illustrating a timing signal used in the data-extracting circuit of FIG. 6.

### DETAILED DESCRIPTION OF THE INVENTION

Embodiments of the present invention will be described in detail, with reference to the accompanying drawings.

<First Embodiment>

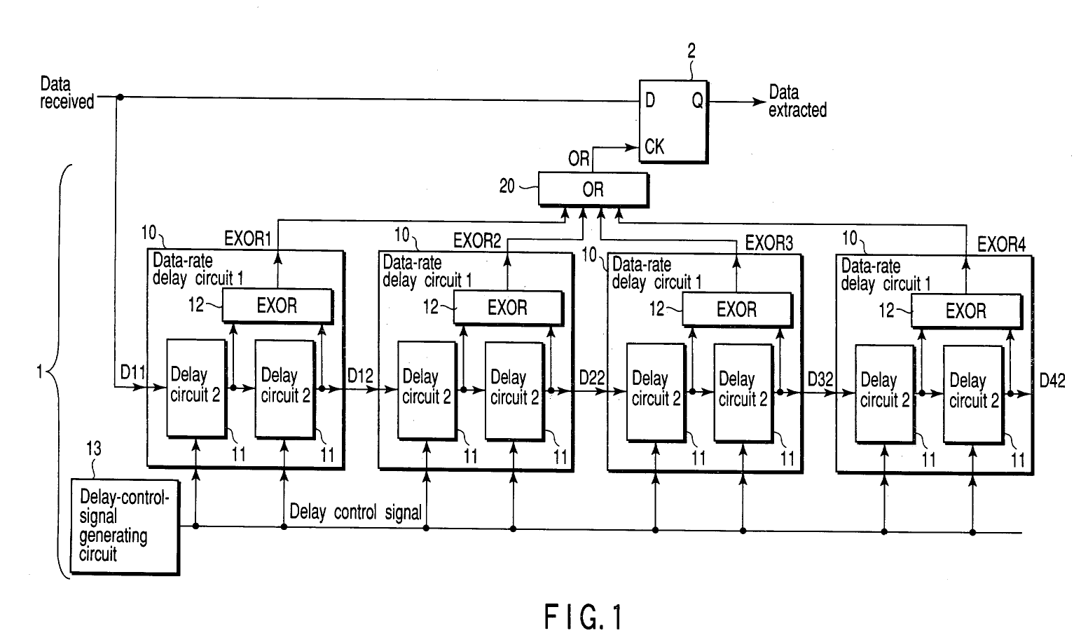

FIG. 1 shows a data-extracting circuit that incorporates a clock-signal generating circuit according to the first embodiment of the present invention. The data-extracting circuit is provided in an integrated circuit. Alternatively, only a part of it is provided in the integrated circuit.

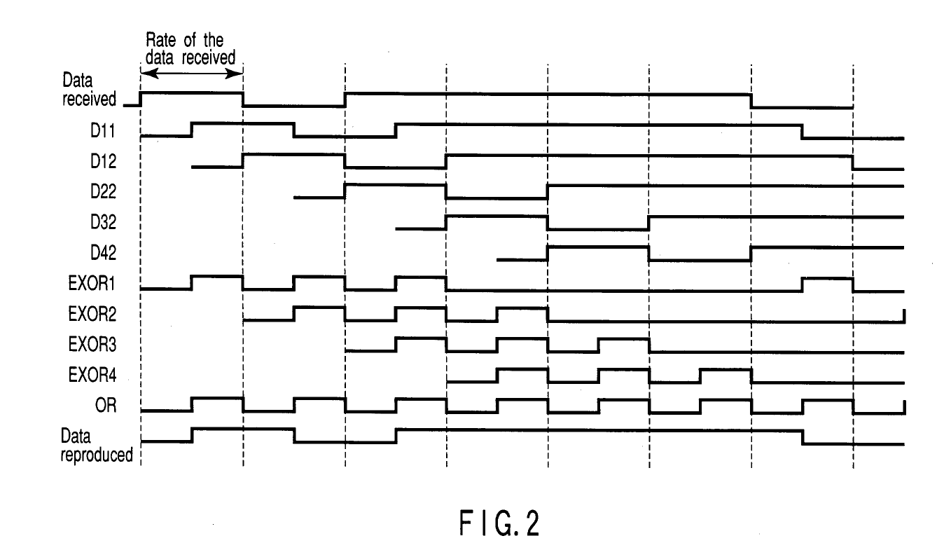

FIG. 2 is a timing chart illustrating various signals and explains the operation of the data-extracting circuit shown in FIG. 1.

As FIG. 1 shows, the data-extracting circuit comprises a clock-signal generating circuit 1 and a data-reproducing circuit 2.

The clock-signal generating circuit 1 includes a plurality of data-rate delay circuits 10, a delay-control-signal generating circuit 13, and a logic circuit 20.

In the clock-signal generating circuit 1, the data-rate delay circuits 10 are connected in cascade. Serial data is input to the delay-rate delay circuit 10 at the first stage. The delay-rate delay circuit 10 at each stage delays the input data by the rate of the serial data and outputs, for each bit of the serial data, a pulse signal that is shifted in phase from the input data by 1/n of the rate of the input serial data (n is an integer). The pulse signals that the data-rate delay circuits 10 have output are supplied to the logic circuit 20.

The logic circuit 20 performs a logic operation on the pulse signals supplied from the data-rate delay circuits 10, generating a logic signal. The logic signal is used as an optimal sampling clock signal that is used to extract data from the serial data. In the present embodiment, the logic circuit 20 is an OR circuit that generates a logic sum of the pulse signals output by the data-rate delay circuits 10.

The data-reproducing circuit 2 receives the optimal sampling clock signal from the logic circuit 20 of the clock-signal generating circuit 1. The data-reproducing circuit 2 is designed to sample the serial data by using the optimal sampling clock signal, thereby to reproduce the data. In this embodiment, the circuit 2 is a flip-flop circuit.

Each of the data-rate delay circuits 10 comprises n variable delay circuits 11 and one pulse-signal output circuit 12. (Note that n is an integer, which is 2 in the present embodiment.) The n variable delay circuits 11 are connected in cascade. They are controlled by a DC voltage for delay control that the delay-control-signal generating circuit 13 has generated. Controlled by the delay control voltage, each variable delay circuit 11 delays the input data by a value smaller than the rate of the serial data. Thus, in each data-rate delay circuit 10, the n variable delay circuits 11 delay the input data by the rate of the serial data. The outputs of the n variable delay circuits 11 are supplied to the pulse-signal output circuit 12.

The pulse-signal output circuit 12 generates a pulse signal from the outputs of the n variable delay circuits 11, for each bit of the serial data. The pulse signal has its phase shifted, by 1/n of the rate of the serial data, from the data input to the data-rate delay circuit 10. The circuit 12 is, for example, a non-coincidence detection circuit that receives the outputs of the n variable delay circuits 11.

In the present embodiment, n=2, the non-coincidence detection circuit 12 is an exclusive-OR circuit, and the non-coincidence detecting circuit 12 can generate a pulse signal whose logic level changes at the midpoint in the bit period of the serial data.

The data-rate delay circuits 10 are provided in the same number as the bits that define the longest bit-length (i.e., four bits in the present embodiment) in which the value of the bits of the input serial data remains unchanged.

The delay-control-signal generating circuit 13 should better adjust the delay control voltage to optimize the delay times of the n variable delay circuits 11 that are provided in each data-rate delay circuit 10.

Thus, in the clock-signal generating circuit 1 incorporated in the data-extracting circuit, the serial data is input to the data-rate delay circuit 10 at the first stage, and each data-rate delay circuit 10 delays the input data by the rate of the serial data. Further, each data-rate delay circuit 10 generates a pulse signal, for each bit of the serial data, that shifts in phase from the input data by half the rate of the input data. The pulse signals output from the data-rate delay circuits 10 are supplied to the logic circuit 20. The logic circuit 20 performs a logic operation on the pulse signals, generating a sampling clock signal that is used to extract data from the serial data input to the data-extracting circuit.

In each data-rate delay circuit 10, two variable delay circuits 11 are connected in cascade. Controlled by the delay control voltage, each variable delay circuit 11 delays the input data by a value smaller than the rate of the serial data. Therefore, the two variable delay circuits 11 delay the input data by the rate of the serial data. The outputs of the variable delay circuits 11 are supplied to the pulse-signal output circuit 12 that is an exclusive-OR circuit. From the outputs of the circuits 11 the pulse-signal output circuit 12 generates a pulse signal, for each bit of the serial data, that has a phase shifted, by half the data rate, from the data input to the data-rate delay circuit 10. It is desired that the pulse signal be one whose logic level changes at the midpoint in the bit period of the serial data.

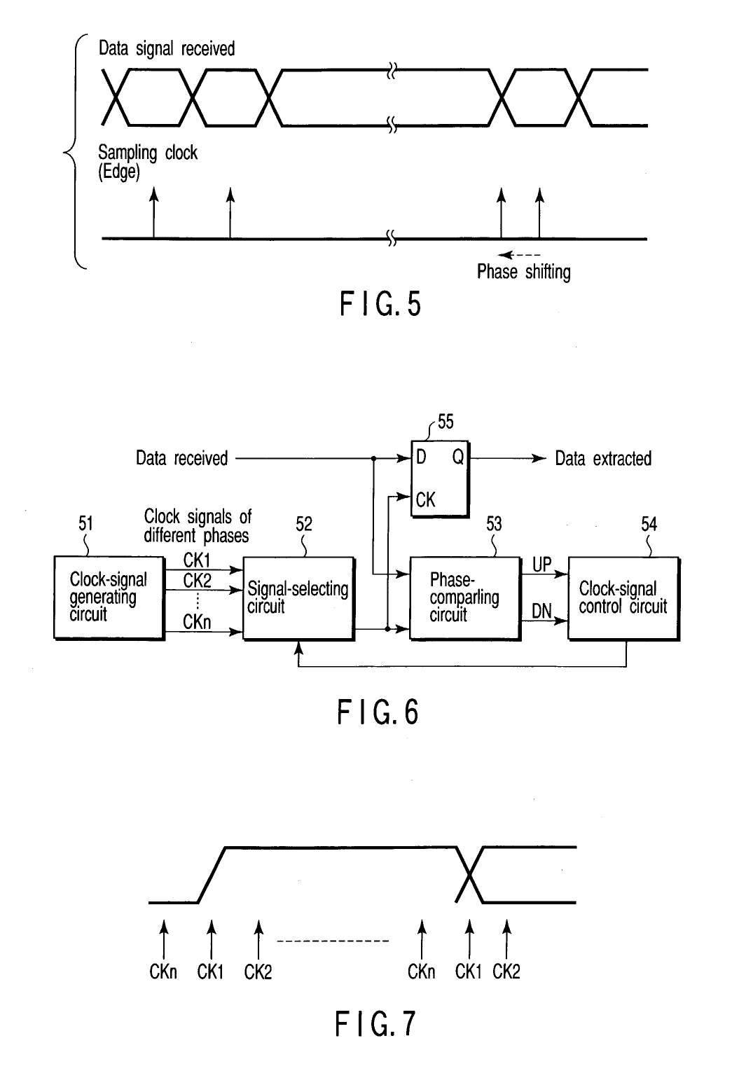

Therefore, so many wires as is required in the conventional data-extracting circuit of FIG. 6 need not be provided, and the wiring pattern of the data-extracting circuit shown in FIG. 1 can be simple.

In the data-extracting circuit of the structure shown in FIG. 1, the clock-signal generating circuit 1 can generate an optimal sampling lock signal within the one-clock period from the first leading (or trailing) edge of the input data. The data-extracting circuit of FIG. 1 can therefore generate reproduced data within the one-clock period, too.

As indicated above, the clock-signal generating circuit 1 has as many data-rate delay circuits 10 as the bits that define the longest bit-length during which the value of the bits of the serial data remains unchanged. Hence, the clock-signal generating circuit of FIG. 1 is fit for use in data-transmitting systems wherein the longest bit-length during which the value of the bits of the input dada remains unchanged is relatively short. The circuit is useful in data-transmitting systems that operate in the Hi-speed mode of the USB 2.0 standard, in which the longest bit-length is a 7-bit length, or in the 8B10B data-transmission systems in which the longest bit-length is a 9-bit length.

<Second Embodiment>

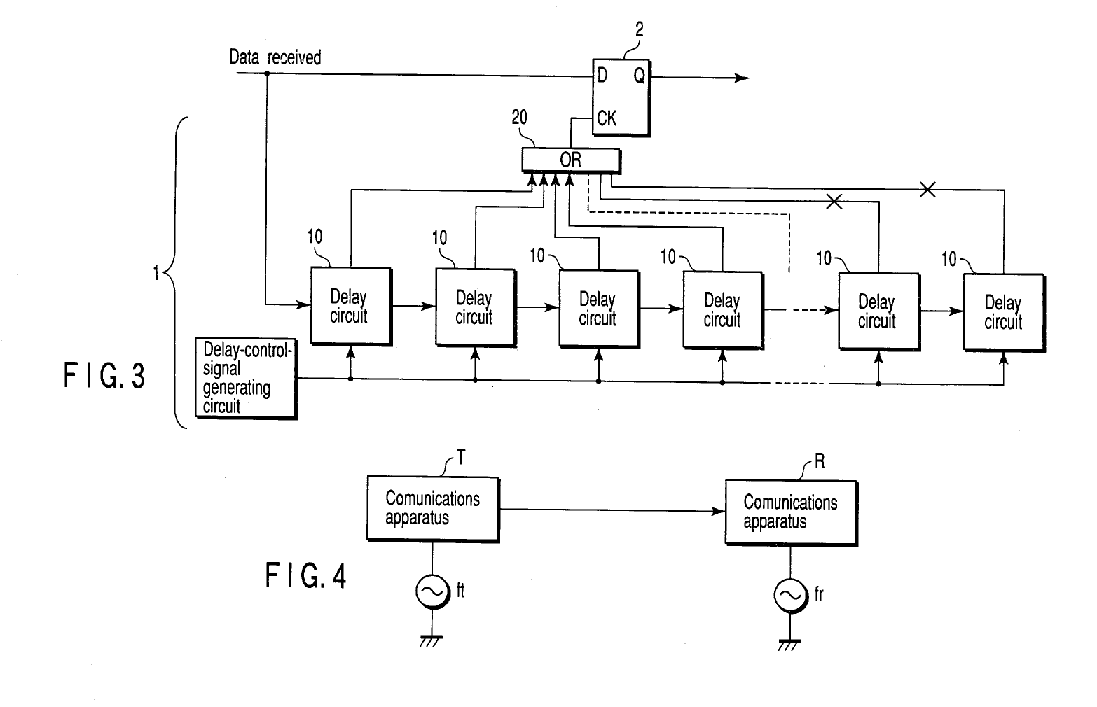

FIG. 3 shows a data-extracting circuit that incorporates a clock-signal generating circuit according to the second embodiment of the present invention.

In the first embodiment as has been described, the clock-signal generating circuit 1 has as many data-rate delay circuits 10 as the bits that define the longest bit-length during which the value of the bits of the input data remains unchanged. The second embodiment is characterized by the clock-signal generating circuit, which can cope with a plurality of systems in which the longest bit-lengths during which the value of the bits of the input data remains unchanged are different from each other.

As FIG. 3 shows, the clock-signal generating circuit 1 has data-rate delay circuits 10 in the same number as the bits that define the longest bit-length of the system that a greater longest bit-length than any other systems for which the second embodiment can work. When the data-extracting circuit is used in any other system, not all data-rate delay circuits 10 are connected to the logic circuit 20. Rather, only some of the circuits 10 are connected to the circuit 20, in the same number as the bits that define the longest bit-length of that system. In FIG. 3, crosses (X) indicate the lines that do not connect those of the data-rate delay circuits 10 which are not used. The components identical to those shown in FIG. 1 are designated by the same reference numerals in FIG. 3.

In the second embodiment, the integrated circuit incorporating the clock-signal generating circuit can cope with a plurality of systems that have different longest bit-lengths. That is, the data-extracting circuit of FIG. 3 can therefore be standardized and can, hence, be manufactured at a low cost.

As has been described, the clock-signal generating circuit according to this invention can generate an optimal sampling clock signal that helps to extract data in synchronism with the inputting of serial data. The data-extracting circuit that incorporates this clock-signal generating circuit need not have so many wires as is required in conventional data-extracting circuits and can reliably reproduce the input data even if the data remains unchanged for a long time.

Additional advantages and modifications will readily occur to those skilled in the art. Therefore, the invention in its broader aspects is not limited to the specific details and representative embodiments shown and described herein. Accordingly, various modifications may be made without departing from the sprint or scope of the general inventive concept as defined by the appended claims and their equivalents.

What is claimed is:

1. A clock-signal generating circuit comprising:
a plurality of data-rate delay circuits which are connected in cascade, the data-rate delay circuit at a first stage being connected to receive serial data, and each of the data-rate delay circuits being configured to delay input data by the rate of the serial data and output, for each bit of the serial data, one pulse signal shifted in phase from the input data by 1/n of the data-rate of the input serial data (n is an integer); and
a logic circuit which synthesizes the pulse signals output from the data-rate delay circuits to output a sampling clock signal for extracting data from the serial data.

2. A clock-signal generating circuit according to claim 1, wherein each of the data-rate delay circuits comprises n variable delay circuits and a pulse signal output circuit, the n variable delay circuits are connected in cascade, each of the n variable delay circuits is controlled by a delay control voltage to delay the input data by a value smaller than the rate of the serial data so that the n variable delay circuits delay the input data by the rate of the serial data, the pulse signal output circuit receives output signals of the n variable delay circuits and outputs, for each bit of the serial data, one pulse signal shifted in phase from the input data by 1/n of the rate of the input serial data (n is an integer).

3. A clock-signal generating circuit according to claim 2, wherein the pulse signal output circuit is a non-coincidence detecting circuit which receives the outputs of the n variable delay circuits.

4. A clock-signal generating circuit according to claim 2, wherein n=2, and the pulse signal output circuit is an exclusive-OR circuit configured to receive the outputs of the n variable delay circuits and output a pulse signal whose logic level changes at a midpoint in a bit period of the serial data.

5. A clock-signal generating circuit according to claim 2, further comprising a delay-control-signal generating circuit which generates the delay control voltage and adjusts the delay control voltage.

6. A clock-signal generating circuit according to claim 1, the data-rate delay circuits are provided in the same number as the bits that define the longest bit-length during which a value of bits of the serial data remains unchanged.

7. A clock-signal generating circuit according to claim 2, the data-rate delay circuits are provided in the same number as the bits that define the longest bit-length during which a value of bits of the serial data remains unchanged.

8. A clock-signal generating circuit according to claim 6, wherein part of the data-rate delay circuits are used.

9. A clock-signal generating circuit according to claim 1, wherein the serial-data is data received in a data-communication.

10. A clock-signal generating circuit comprising:
a plurality of data-rate delay circuits which are connected in cascade, the data-rate delay circuit at a first stage being connected to receive serial data, and each of the data-rate delay circuits being configured to delay input data by the rate of the serial data and output, for each bit of the serial data, one pulse signal shifted in phase from the input data by 1/n of the data-rate of the input serial data (n is an integer);
a logic circuit which performs a logic operation OR on the pulse signals output from the data-rate delay circuits to output a sampling clock signal; and
a data-reproducing circuit which receives the serial data and samples the serial data by using the sampling clock signal output from the logic circuit to reproduce data.

11. A clock-signal generating circuit according to claim 10, wherein the serial-data is data received in a data-communication.
